(19) United States
(12) Patent Application Publication
(10) Pub. No.: US 2013/0033270 A1
(43) Pub. Date: Feb. 7, 2013

(54) ELECTROMAGNETIC INTERFERENCE TEST SYTEM WITH SELF-CHECKING FUNCTION AND SELF-CHECKING METHOD

(71) Applicant: XIAO-LIAN HE, Shenzhen City (CN)

(72) Inventor: XIAO-LIAN HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/335,960

(22) Filed: Dec. 23, 2011

(30) Foreign Application Priority Data
Aug. 3, 2011 (CN) 201110220783.0

(51) Int. Cl. G01R 27/00

(52) U.S. Cl. 324/628

(57) ABSTRACT

An electromagnetic interference (EMI) test system with self-checking function for detecting electromagnetic interference includes a signal source, a line impedance stabilization network (LISN), a coupling decoupling network (CDN), an impedance stabilization network (ISN) and a receiver. The signal source provides an electronic signal, the LISN separates interference signal from the electronic signal. The CDN outputs a coupling signal, and the ISN separates interference signal from the signal from the CDN. The receiver figures out current signal strength of each frequency points of the signal from the ISN and compares the current signal strength with a reference value to determine whether the EMI test system works normally according to the comparison.

### BACKGROUND

1. Technical field

The disclosure generally relates to test systems and self-checking methods, and more particularly to an electromagnetic interference (EMI) test system with self-checking function and a self-checking method.

2. Description of the Related Art

Electromagnetic interference (EMI) is disturbance that affects a communication system due to either electromagnetic induction or electromagnetic radiation emitted from an external source. The disturbance may interrupt, obstruct, or otherwise degrade or limit the effective performance of power ports and signal ports of the communication system. Thus, a line impedance stabilization network (LISN) is used to test the power ports of the communication system, and an impedance stabilization network (ISN) is used to test the signal ports of the communication system.

In use, the LISN, ISN and other devices (e.g., signal generator) form a test system to detect the power ports and the signal ports. However, the test system cannot carry out a self-checking function and needs to be repeatedly checked and adjusted manually to obtain correct and accurate test results, which may cause inaccurate test results and take more test time.

Therefore, there is room for improvement within the art.

### BRIEF DESCRIPTION OF THE DRAWINGS

Many aspects of an EMI test system with self-checking function and self-checking method can be better understood with reference to the following drawings. The components in the drawings are not necessarily drawn to scale, the emphasis instead being placed upon clearly illustrating the principles of the EMI test system with self-checking function and self-checking method. Moreover, in the drawings, like reference numerals designate corresponding parts throughout the several views.

Wherever possible, the same reference numbers are used throughout the drawings to refer to the same or like elements of an embodiment.

FIG. 1 is a block view of one embodiment of an EMI test system with self-checking function of the disclosure.

FIG. 2 is a flowchart of a self-checking method, according to an embodiment of the disclosure.

### DETAILED DESCRIPTION

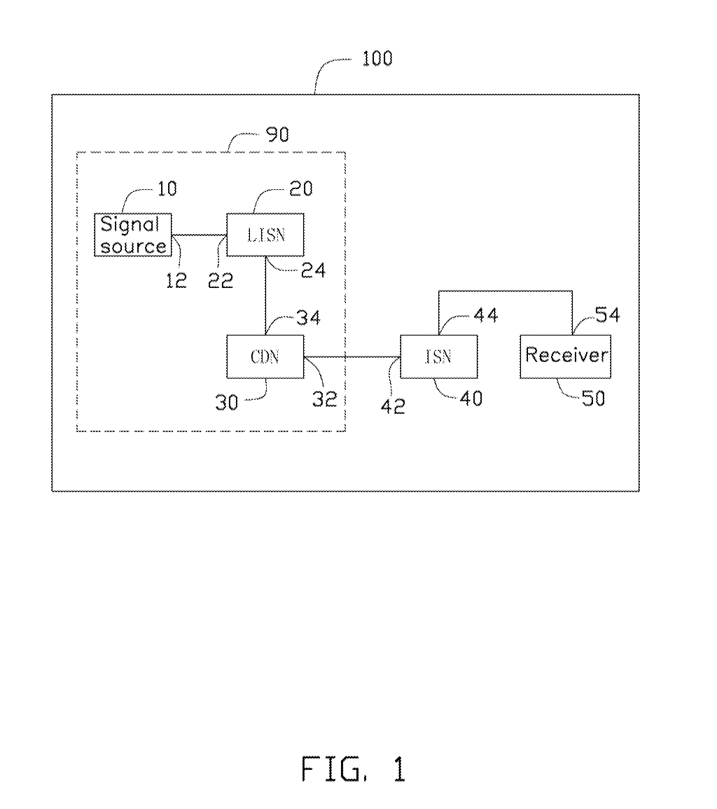

FIG. 1 shows a block view of one embodiment of an electromagnetic interference (EMI) test system with self-checking function 100 of the disclosure. In this embodiment, the EMI test system 100 includes a signal source 10, a line impedance stabilization network (LISN) 20, a coupling decoupling network (CDN) 30, an impedance stabilization network (ISN) 40, and a receiver 50.

The signal source 10 can be a signal generator that generates repeating or non-repeating electronic signals (in either the analog or digital domains). In this embodiment, the signal source 10 provides and outputs electronic signals in a predefined frequency range of about 150 kHz-30 MHz, and a step length of sweeping frequency of 250 kHz. The signal source 10 transmits different electronic signals with predetermined signal intensities at corresponding frequency points. For example, when the signal source 10 operates at the frequency point of 10.0005 MHz, the signal strength of the electronic signal is substantial 53.49 dBuV; the signal strength of the electronic signal is substantial 51.81 dBuV at the frequency point of 14.0004 MHz. The signal source 10 includes a signal power port 12 that is used as an output port of the signal source 10 to output the electronic signals.

The LISN 20 includes a LISN power port 22 and a LISN radio frequency (RF) port 24. The power port 22 is electrically connected to the signal power port 12 of the signal source 10 through a coaxial cable. The LISN 20 can create a known impedance on the power port 22 during EMI testing to allow for measurement of the EMI existing on the power port 22, and separate interference signals from the electronic signal and transmit the processed signal to the CDN 30 via the LISN RF port 24. The operating frequency range of the LISN 20 is 150 kHz-30 MHz. The LISN RF port 24 used as an output port is an N-type connector, and has an output resistance of about 50 Ohm.

The CDN 30 includes a CDN signal port 32 and a CDN RF port 34. The CDN RF port 34 is used as an input port and is electrically connected to the RF port 24 of the LISN 20 through a coaxial cable. The CDN 30 is capable of isolating and coupling the interference signals during EMI testing and outputting coupling signals to increase electronic signal strength and reduce signal loss during transmission. The CDN 30 has an operating frequency range of about 150 kHz-30 MHz, and the CDN RF port 34 has an input resistance of about 50 Ohm corresponding to that of the LISN RF port 24. The CDN signal port 32 is used as an output port of the CDN 30, and has an output resistance of about 150 Ohm.

The signal source 10, the LISN 20 and the CDN 30 cooperatively form a transmitting system 90. The transmitting system 90 outputs and provides predetermined electronic signals that are used as testing signals for the ISN 40.

The ISN 40 includes an ISN signal port 42 and an ISN RF port 44, and the ISN signal port 42 is in electronic communication with the CDN signal port 32 of the CDN 30.

In this embodiment, the ISN 40 is designed to provide stable impedance during EMI testing to allow for measurements of EMI of the signal port 42. The operating frequency range of the ISN 40 is about 150 kHz-30 MHz. The RF port 44 is an N-type output port of the ISN 40, and has an output resistance of about 50 Ohm. The ISN signal port 42 is used as an input port of the ISN 40 and the resistance of the signal port 42 is about 150 Ohm corresponding to that of the signal port 32 of the CDN 30.

The receiver 50 is in electronic communication with the RF port 44 of the ISN 40 via a coaxial cable to receive the signals from the ISN 40, and measure and figure out the signal strength of the corresponding frequency points. For example, the signal strength corresponding to the frequency point of 10.0005 MHz is about 43.13 dBuV; the signal strength corresponding to the frequency point of 14.0004 MHz is about 41.28 dBuV. The signal strength of the frequency point measured by the receiver 50 plus transmission loss and circuit loss is substantially equal to the signal strength of the corresponding frequency point transmitted by the signal source 10. For example, the signal strength of the frequency point of 14.0004 Mz transmitted by the signal source 10 is 51.81 dBuV as foresaid, so the transmission loss and the circuit loss are about 10.53 dBuV.

The receiver 50 includes a receiving port 54 electrically connected to the ISN RF port 44 of the ISN 40 via the coaxial cable. The operating frequency range of the receiver 50 is about 150 kHz-250 MHz, the receiving port 54, whose resistance is about 50 Ohm, is used as an input port of the receiver 50.

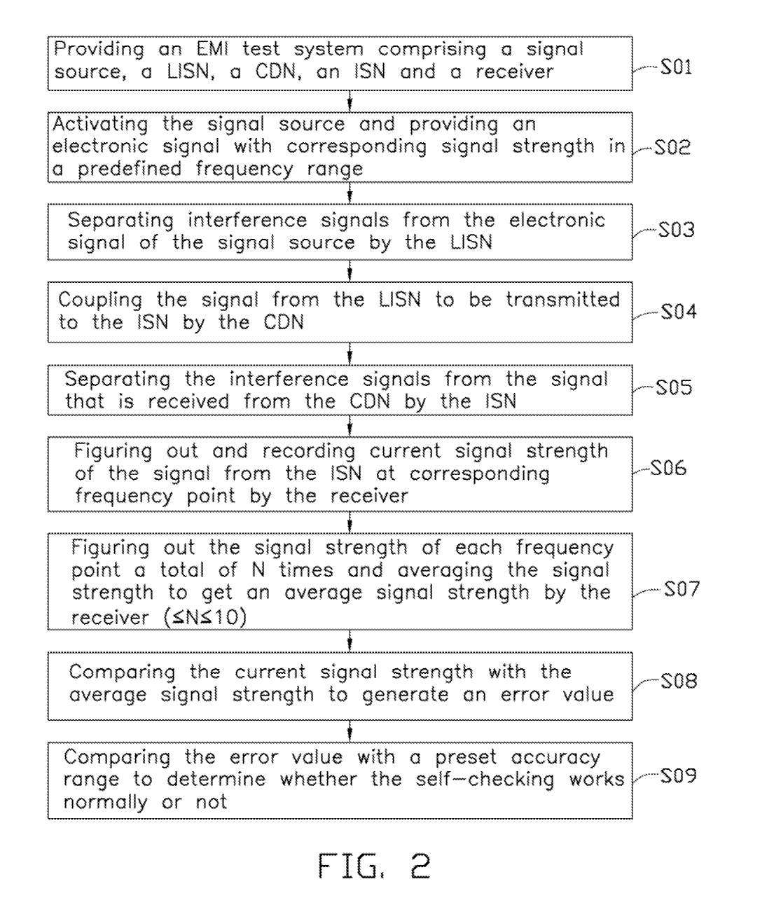

Also referring to FIG. 2, a test method for enabling the EMI test system 100 to execute self-checking function according to an embodiment of the disclosure is depicted. The test method can use the aforementioned EMI test system 100, and may include at least the following steps.

In step S0L the signal 10, the LISN 20, the CDN 30, the ISN 40 and the receiver 50 are electrically connected in series to form the EMI test system 100.

In step S02, the signal source 10 is activated, and provides and transmits an electronic signal with corresponding signal strength in a predefined frequency range of about 150 kHz-30 MHz by increasing the frequency of the step length of about 250 kHz per time. For example, when the signal source 10 works at the frequency point of 26.0001 MHz, the signal strength of the electronic signal is about 48.61 dBuV.

In step S03, the LISN 20 receives the electronic signals from the signal source 10 through the power port 22 of the LISN 20, and separates the interference signals of the power port 22 from the electronic signals.

In step S04, the CDN 30 receives the signals from the RF port 24 via the RF port 34, and the signals are coupled to the signal port 32 and are transmitted to the ISN 40 through the signal port 32.

In step S05, the ISN 40 receives the signals from the signal port 32 of the CDN 30 through the signal port 42 of the ISN 40, and separates the interference signals of the signal port 42 from the signals of the CDN 30.

In step S06, the receiver 50 receives the signals from the ISN 40, and measures and figures out the current signal strength of the corresponding frequency points. For example, the current signal strength of the frequency point of 26.0001 MHz is 37.67 dBuV.

In step S07, the receiver 50 figures out and records the signal strength of each frequency point a total of N times, and average and figure out the total of the signal strength to get an average signal strength of each frequency point that is used as a reference value. For example, the receiver 50 figures out the signal strength of the frequency point of 26.0001 MHz a total of N times, where 5<=N<=10 and the average signal strength is about 37.65 dBuV.

In step S08, the receiver 50 compares the current signal strength with the reference value to generate an error value. For example, the current signal strength of the frequency point of 26.0001 MHz is 37.67 dBuV, and the reference value is 37.65 dBuV, so the error value is about 0.02 dBuV.

In step S09, the receiver 50 compares the error value with a preset accuracy range (e.g., ±2 dBuV) to determine whether the self-checking 100 works normally or not. For example, the reference value of the frequency point of 26.0001MHz is 37.65dBuV, if the current signal strength of the frequency point of 26.0001 MHz is 37.67 dBuV, the error value is 0.02 dBuV that is within the accuracy range, the EMI test system 100 works normally. If the current signal strength of the frequency point of 26.0001 MHz is 35.15 dBuV, the error value is 2.50 dBuV that is without the preset accuracy range, the EMI test system 100 works abnormally.

In summary, the EMI test system 100 of the disclosure can test the EMI of communication system, and simultaneously execute self-checking function to check the RF ports and the power ports of the LISN 20 and the ISN 40 during EMI testing. Thus, the EMI test system 100 can get accurate test results and waste less test time.

In the present specification and claims, the word “a” or “an” preceding an element does not exclude the presence of a plurality of such elements. Further, the word “comprising” does not exclude the presence of other elements or steps than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. An electromagnetic interference (EMI) test system with self-checking function for detecting electromagnetic interference, the EMI test system comprising:
a signal source for providing an electronic signal;
a line impedance stabilization network (LISN) electrically connected to the signal source to separate interference signal from the electronic signal;
a coupling decoupling network (CDN) electrically connected to the LISN to output coupling signal;
an impedance stabilization network (ISN) electrically connected to the CDN; and
a receiver electrically connected to the ISN, wherein the ISN separates interference signal from the signal transmitted from the CDN, the receiver figures out current signal strength of each frequency points of the signal transmitted from the ISN and compares the current signal strength with a reference value to determine whether the EMI test system works normally according to the comparison.

2. The EMI test system with self-checking function as claimed in claim 1, wherein the signal source is a signal generator whose operating frequency is 150 kHz-30 MHz, the signal source comprises a signal power port that is used as output port of the signal source to output the electronic signal.

3. The EMI test system with self-checking function as claimed in claim 2, wherein the LISN comprises a power port and a radio frequency (RF) port, the power port is electrically connected to the signal power port of the signal source through a coaxial cable, the operating frequency range of the LISN is 150 kHz-30 MHz, and the RF port of the LISN used as an output port is an N-type connector whose resistance is substantial 50 Ohm.

4. The EMI test system with self-checking function as claimed in claim 3, wherein the CDN comprises a signal port and a RF port, the RF port is used as an input port and is electrically connected to the RF port of the LISN through a coaxial cable, the operating frequency range of the CDN is substantial 150 kHz-30 MHz, the resistance of the RF port of the CDN is 50 Ohm corresponding to that of the RF port of the LISN, and the signal port of the CDN whose resistance is 150 Ohm is used as an output port of the CDN.

5. The EMI test system with self-checking function as claimed in claim 4, wherein the ISN comprises a signal port and a RF port, and the signal port of the ISN is in electronic communication with the signal port of the CDN, and the operating frequency range of the ISN is 150 kHz-30 MHz, the RF port of the ISN, whose resistance is 50 Ohm, is an N-type output port of the ISN, and the signal port of the ISN is used as an input port and the resistance of the signal port of the ISN is 150 Ohm corresponding to that of the signal port of the CDN.

6. The EMI test system with self-checking function as claimed in claim 5, wherein the receiver is in electronic communication with the RF port of the ISN via a coaxial cable to receive the signals from the ISN, and measure and figure out the signal strength of the corresponding frequency points, and the signal strength of the frequency point measured by the receiver plus transmission loss and circuit loss is substantially equal to the signal strength of the corresponding frequency point transmitted by the signal source.

7. The EMI test system with self-checking function as claimed in claim 5, wherein receiver comprises a receiving port electrically connected to the RF port of the ISN via the coaxial cable, the operating frequency range of the receiver is 150 kHz-250 MHz, the receiving port whose resistance is 50 Ohm is used as an input port of the receiver.

8. The EMI test system with self-checking function as claimed in claim 1, wherein the receiver compares the current signal strength with the reference value to generate an error value according to the comparison.

9. The EMI test system with self-checking function as claimed in claim 8, wherein the receiver compares the error value with a preset accuracy range to determine whether the self-checking works normally or not according to the comparison, if the error value is within the error range, the EMI test system works normally, if the error value is without the error range, the EMI test system works abnormally.

10. The EMI test system with self-checking function as claimed in claim 1, wherein the signal source, the LISN and the CDN form a transmitting system to output and provide predetermined electronic signals which are used as testing signals for the ISN.

11. A test method for executing self-checking function, the test method comprising steps of:
providing an electromagnetic interference (EMI) test system comprising a signal source, a line impedance stabilization network (LISN), a coupling decoupling network (CDN), an impedance stabilization network (ISN) and a receiver;
activating the signal source and providing an electronic signal with corresponding signal strength in a predefined frequency range;
separating interference signals from the electronic signal of the signal source by the LISN;
coupling the signal from the LISN to be transmitted to the ISN by the CDN;
separating the interference signals from the signal that is received from the CDN by the ISN; and
figuring out and recording current signal strength of the signal from the ISN at corresponding frequency point by the receiver.

12. The test method as claimed in claim 11, further comprising figuring out the signal strength of each frequency point a total of N times and averaging the signal strength to get an average signal strength of each frequency point by the receiver.

13. The test method as claimed in claim 12, wherein 5<=N<=10.

14. The test method as claimed in claim 12, further comprising comparing the current signal strength with the average signal strength to generate an error value.

15. The test method as claimed in claim 13, further comprising comparing the error value with a preset accuracy range to determine whether the self-checking works normally or not.
